(19) United States
(12) Patent Application Publication
(10) Pub. No.: US 2008/0306699 A1
(43) Pub. Date: Dec. 11, 2008

(54) Method For Measuring the Power Consumption Time of a Cdma Mobile Terminal

(75) Inventors: Hongli Peng, Guangdong Province (CN); Jiangjiang Chen, Guangdong Province (CN); Biqin Tu, Guangdong Province (CN)

Correspondence Address: THELEN LLP, P. O. BOX 640640, SAN JOSE, CA, 95164-0640, US

(73) Assignee: ZTE Corpoaration, Guang Province (CN)

(21) Appl. No.: 11/658,245

(22) PCT Filed: Feb. 23, 2005
(86) PCT No.: PCT/CN05/00218

§ 371 Date: Jan. 22, 2007

(30) Foreign Application Priority Data
Jul. 23, 2004 (CN) 200410050815.7

(51) Int. Cl. G01R 21/00

(52) U.S. Cl. 702/61

(57) ABSTRACT

The present invention relates to a method for measuring the power consumption time of a CDMA mobile terminal, and the method comprises the steps of wire-connecting a terminal to be measured with a CDMA network simulator; measuring the standby power consumption time of said terminal to be measured in standby mode, and calculating a normalized power consumption time length T̅_{Idle} of the standby power consumption time to specified battery capacity; and measuring the operating power consumption time of said terminal to be measured in operating mode, and calculating a normalized power consumption time T̅_{Normal} of the operating power consumption time to specified battery capacity. Directed to the present status that descriptive parameters evaluating power consumption time of a CDMA mobile terminal in network environment and measuring technology for the descriptive parameters are blank, the present invention adopts simulative CDMA network environment and obtains descriptive parameters of the power consumption time of a CDMA mobile terminal conveniently by measuring and calculating the power consumption time of a CDMA mobile terminal under the environment. The present invention is low in requirement for environment, and convenient and easy to operate.

### FIELD OF THE INVENTION

The present invention relates to a method for measuring the power consumption time of a CDMA mobile terminal, especially a method for measuring the power consumption time of the CDMA mobile terminal through a wire-connection measuring and calculating manner.

### BACKGROUND ART

With the fast increase of the number of the CDMA users, CDMA mobile terminals are widely used, however, with the gradually enhanced requirement on using CDMA mobile terminals, the users hope that CDMA mobile terminals they used have longer standby time and longer talk time, for which those skilled in the field make researches and hope to find the root reason why a CDMA mobile terminal consumes so much power so as to bring forward specific solutions for optimizing the network and improving the mobile terminal.

While at present, the technologies evaluating the descriptive parameters for the power consumption time of a CDMA mobile terminal in network environment and measuring the descriptive parameters are blank. Hence, the present invention produces a method which can simply and efficiently evaluate the descriptive parameters for the power consumption time of a CDMA mobile terminal and obtain such descriptive parameters, which has become one of the problems that should be first solved for those skilled in the field to find the above mentioned reason why CDMA mobile terminal consumes too much power.

### SUMMARY OF THE INVENTION

In view of the present status that the technologies evaluating the descriptive parameters for the power consumption time of a CDMA mobile terminal in network environment and measuring the descriptive parameters are blank, the present invention aims to provide a method for measuring the power consumption time of a CDMA mobile terminal, and for this method, a terminal to be measured is wire-connected with a CDMA network simulator by radio frequency cables, thereby the standby time and the talk time of a mobile phone are measured.

In order to realize the above objects, the method for measuring the power consumption time of a CDMA mobile terminal comprises the following steps:

step 1, wire-connecting the terminal to be measured with the CDMA network simulator;

step 2, measuring the standby power consumption time of the terminal to be measured in a standby mode, and calculating normalized power consumption time T̅_{Idle} of the standby power consumption time to specified battery capacity;

step 3, measuring the operating power consumption time of the terminal to be measured in a operating mode, and calculating the normalized power consumption time T̅_{Normal} of the operating power consumption time to the specified battery capacity.

From the above mentioned technical solutions, it is clear that the present invention is directed to the present status that the technologies evaluating the descriptive parameters for the power consumption time of the CDMA mobile terminal in network environment and measuring the descriptive parameters are blank, the present invention adopts simulative CDMA network environment, and obtains descriptive parameters of the power consumption time of CDMA mobile terminal conveniently by measuring and calculating the power consumption time of the CDMA mobile terminal under the environment. The environment requirement needed by the present invention is low, and the present invention is convenient and easy to operate.

The present invention is further described below in detail in connection with specific embodiment and drawings thereof.

### BRIEF DESCRIPTION OF THE DRAWINGS

FIG. 1 is a schematic flow chart of the testing principle of the present invention.

FIG. 2 is a schematic flow chart of creating measurement environment of the present invention.

FIG. 3 is a schematic view of measuring the RF cable connection in the method of the present invention.

FIG. 4 is a schematic flow view of measuring the standby power consumption time of the terminal to be measured and normalizing the same in the present invention.

FIG. 5 is a schematic flow view of measuring the operating power consumption time of the terminal to be measured and normalizing the same in the present invention.

### EMBODIMENTS FOR CARRYING OUT THE PRESENT INVENTION

The basic idea of the present invention is to treat the terminal to be measured as a black box, that is, it does not relate to the specific operating process of the terminal to be measured, and then to define the measuring environment of the terminal to be measured. The standby time and talk time (operating mode) in the present environment can be measured through setting and checking the operating mode of the terminal and meanwhile defining the signal quality of certain voice business, and finally the standby time and the talk time to specified battery capacity are normalized, thereby the normalized power consumption time of the terminal to be measured is obtained.

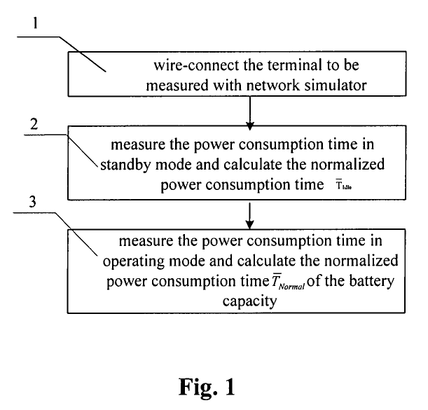

The principle and processes of the present invention as shown in the flow chart of FIG. 1 comprise the following steps:

step 1, wire-connecting the terminal to be measured with the CDMA network simulator and creating measurement environment;

step 2, measuring the standby power consumption time of the terminal to be measured in a standby mode, and calculating normalized power consumption time T̅_{Idle} of the standby power consumption time to the specified battery capacity; and

step 3, measuring the operating power consumption time of the terminal to be measured in an operating mode and calculating the normalized power consumption time T̅_{Normal} of the operating power consumption time to the specified battery capacity.

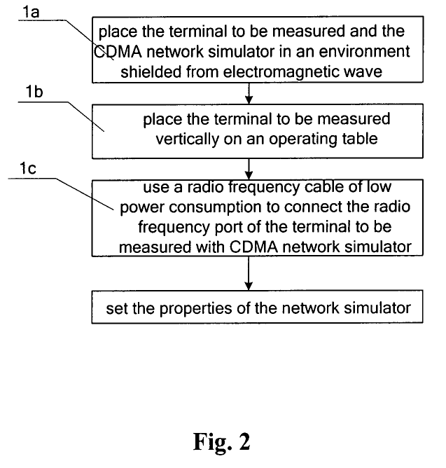

The specific processes and manners as well as the operation process of wire-connecting the terminal to be measured with the CDMA network simulator and creating measurement environment are shown in FIG. 2, and it comprises the following steps:

step 1a, place said terminal to be measured and said CDMA network simulator in an environment which is shielded from outer electromagnetic wave, and said environment can be a electromagnetic wave shielded chamber with a space of 3 m*3 m*2.7 m.

step 1b, place said terminal to be measured vertically on a measurement table which is made from materials of low electromagnetic loss.

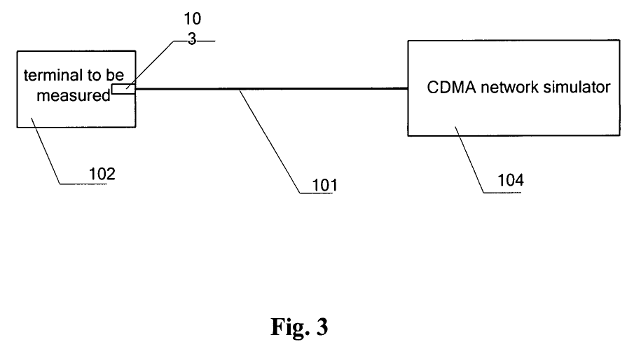

step 1c, connect the radio frequency port of the terminal to be measured with one end of a radio frequency cable of low power consumption whose loss is known, and the other end of the radio frequency cable of low power consumption connects the CDMA network simulator. As shown in FIG. 3, the length of the RF cable 101 of low power consumption having high frequency choke capability is about 0.5 m. The radio frequency port 103 (also referred to as terminal connector port or antenna interface) of the terminal 102 to be measured is connected with one end of the radio frequency cable 101 of low power consumption whose loss is known, and the other end of the radio frequency cable 101 of low power consumption connects with the CDMA network simulator 104 (also referred to as CDMA base station simulator or terminal tester), thereby creating a simulative CDMA communication link.

After creating the measurement environment for the terminal to be measured, the descriptive parameters of the power consumption time of the terminal to be measured can be measured and calculated by setting the properties of the CDMA network simulator 104.

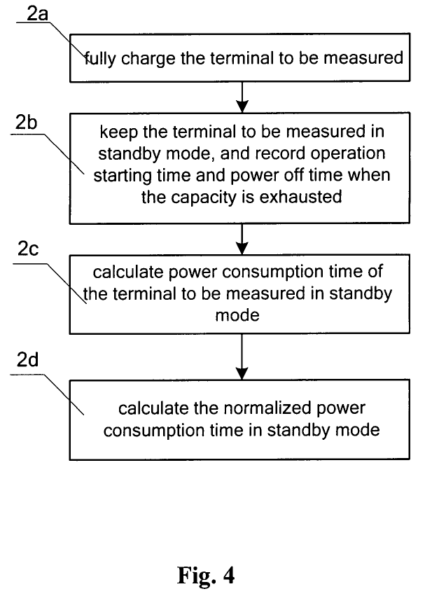

One specific process for actually measuring and calculating the descriptive parameters of the standby power consumption time of the CDMA terminal to be measured is shown in the flow chart of FIG. 4, and it comprises the following steps:

step 2a, fully charge said terminal to be measured, and suppose that I (mAh) is the total battery capacity consumed by the terminal to be measured from power on to power off in the standby mode; suppose that normalized battery capacity in the standby mode is I₀;

step 2b, keep said terminal to be measured in the standby mode, and record standby starting time T_{idle,1} (hour) and standby power off time T_{Idle,2} (hour) when said terminal to be measured has consumed all the capacity of the battery;

step 2c, calculate power consumption time T_{Idle} of said terminal to be measured in the standby mode, and the calculation formula is T_{Idle}=T_{Idle,2}−T_{Idle,1} (hour); and

step 2d, calculate normalized power consumption time T̅_{Idle} of said standby power consumption time to the specified battery capacity, and the formula is

$${\overline{T}}_{Idle} = \frac{I \times {T}_{Idle}}{{I}_{0}} ( hour ) .$$

During testing, keep the terminal to be measured in standby operating state, and if the terminal to be measured is a flip one, open the upper flip to the most extent; the battery is the qualified battery which is configured for the terminal to be measured and has been used no more than 6 months; audio frequency is equipped with external fixed audio frequency device; backlight of the terminal to be measured is set in closed state or in darkest state; the properties of the network simulator are calibrated, wherein operating parameters comprises: frequency, defining according to corresponding test regulations; power: power grade 3 is employed for 800 Mhz as the emission power of MS, and power grade 2 is employed for 1900 Mhz as the emission power of MS.

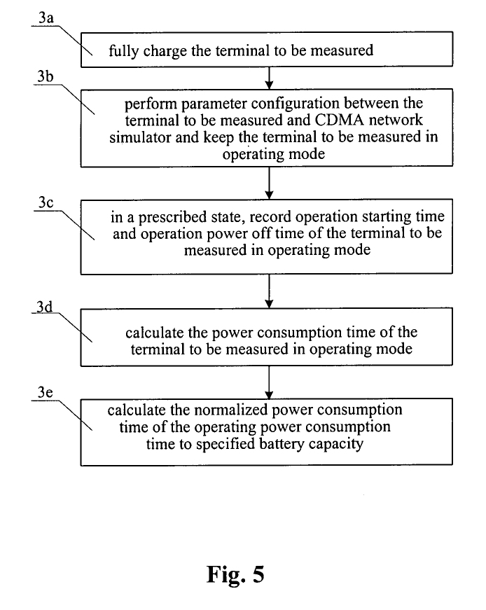

One specific process for actually measuring and calculating the descriptive parameters of the operating power consumption time of the CDMA terminal to be measured is shown in the flow chart of FIG. 5, and it comprises the following steps:

step 3a, fully charge said terminal to be measured, and suppose that I′ (mAh) is the total capacity consumed by the terminal to be measured from power on to automatic power off in the operating mode. The operating mode comprises talk state. Suppose that the normalized battery capacity in the operating mode is I′₀ (mAh).

step 3b, perform parameter configuration between said terminal to be measured and said CDMA network simulator, and keep said terminal to be measured in the operating mode.

step 3c, in a state of prescribed and stable frequency, power and voice transmission QOS, record the operation starting time T_{Normal 1} (hour) of said terminal to be measured in the operating mode, and the operation power off time T_{Normal 2} (hour) when said terminal to be measured has consumed all the capacity.

step 3d, calculate the power consumption time T_{Normal} (hour) of said terminal to be measured in the operating mode, and the calculation formula is T_{Normal}=T_{Normal 2}−T_{Normal 1} (hour).

step 3e, calculate normalized power consumption time of the operating time to

specified battery capacity T̅_{Normal}, and the calculation formula is

$${\overline{T}}_{Normal} = \frac{{I}^{′} \times {T}_{Normal}}{{I}_{0}^{′}} ( hour ) .$$

What is claimed is:

1. A method for measuring the power consumption time of a CDMA mobile terminal, characterized in comprising the following steps:
step 1, wire-connecting a terminal to be measured with a CDMA network simulator;
step 2, measuring the standby power consumption time of the terminal to be measured in standby mode, and calculating the normalized power consumption time T̅_{Idle} of the standby power consumption time to specified battery capacity; and
step 3, measuring the operating power consumption time of the terminal to be measured in operating mode, and calculating the normalized power consumption time T̅_{Normal} of the operating power consumption time to the specified battery capacity.

2. The method for measuring the power consumption time of a CDMA mobile terminal according to claim 1, characterized in that said step 1 specifically comprises the following steps:
step 1a, placing said terminal to be measured and said CDMA network simulator in an environment which is shielded from outer electromagnetic wave;
step 1b, placing said terminal to be measured vertically on a measurement table which is made from materials of low electromagnetic loss; and
step 1c, connecting the radio frequency port of the terminal to be measured with one end of a radio frequency cable of low power consumption whose loss is known, and connecting the other end of the radio frequency cable of low power consumption to the CDMA network simulator.

3. The method for measuring the power consumption time of a CDMA mobile terminal according to claim 2, characterized in that said step 2 specifically comprises the following steps:
step 2a, fully charging said terminal to be measured and supposing that I is the total battery capacity consumed by the terminal to be measured from power on to automatic power off in standby mode;
step 2b, keeping said terminal to be measured in standby mode, and recording power on time T_{Idle,1} and power off time T_{Idle,2} when said terminal to be measured has consumed all the capacity of the battery;
step 2c, calculating the power consumption time T_{Idle} of said terminal to be measured in standby mode: T_{Idle}=T_{Idle,2}−T_{Idle,1}; and
step 2d, calculating the normalized power consumption time T̅_{Idle} of said standby power consumption time to specified battery capacity:
$${\overline{T}}_{Idle} = \frac{I \times {T}_{Idle}}{{I}_{0}} ;$$
wherein I₀ is the normalized battery capacity in standby mode.

4. The method for measuring the power consumption time of a CDMA mobile terminal according to claim 3, characterized in that said step 3 specifically comprises the following steps:
step 3a, fully charging said terminal to be measured and supposing that I′ is the total capacity consumed by the terminal to be measured from power on to automatic power off in operating mode; the operating mode comprising talk state;
step 3b, performing parameter configuration between said terminal to be measured and said CDMA network simulator, and keeping said terminal to be measured in operating mode;
step 3c, in a state of prescribed and stable frequency, power and voice transmission QOS, recording the operation starting time T_{Normal 1} of said terminal to be measured in operating mode and the power off time T_{Normal 2} when said terminal to be measured has consumed all the capacity;
step 3d, calculating the power consumption time T_{Normal} of said terminal to be measured in operating mode: T_{Normal}=T_{Normal 2}−T_{Normal 1}; and
step 3e, calculating the normalized power consumption time T̅_{Normal} of the operating power consumption time to the specified battery capacity:
$${\overline{T}}_{Normal} = \frac{{I}^{′} \times {T}_{Normal}}{{I}_{0}^{′}} ;$$
wherein I′₀ is the normalized battery capacity in operating mode.
